(19) United States
(12) Patent Application Publication
(10) Pub. No.: US 2025/0370023 A1
(43) Pub. Date: Dec. 4, 2025

(54) DIAGNOSTIC AND TESTING MODULE FOR ELECTRICALLY POWERED MACHINE

(71) Applicant: Caterpillar Inc., Peoria, IL (US)

(72) Inventors: Michael R Garrabrant, Dunlap, IL (US); Rien William O'steen, Saint Johns, FL (US); Eric M. Andris, Dunlap, IL (US); Luke Allen Ketcham, Peoria, IL (US); Adrian Stefan Spanoche, Yorkville, IL (US); Adam Mitchell, Carol Stream, IL (US)

(73) Assignee: Caterpillar Inc., Peoria, IL (US)

(21) Appl. No.: 18/676,108

(22) Filed: May 28, 2024

(51) Int. Cl. G01R 31/00; G01R 1/067; G01R 31/52

(52) U.S. Cl. CPC G01R 31/006; G01R 1/06777; G01R 31/52

(57) ABSTRACT

A diagnostic and testing module for an electrically powered vehicle integrates multiple high-voltage buses for assessment while protecting personnel from accessing equipment energized at hazardous voltages. The consolidated module contains circuitry for assessing each high-voltage bus, including checking for ground faults, generating and distributing a priming voltage before energization of the buses, and identifying a bus voltage exceeding a predetermined hazardous level. A protective wall separates the high-voltage buses and circuitry at a rear of the module from a probing block at a front of the module. Lamps within the protective wall warn of energized bus voltages above the hazardous level. If the lamps are not illuminated, personnel can verify de-energized bus voltages using test points within the probing block and then install a grounding bar across all test points to ensure de-energization and prevent inadvertent re-energization.

### TECHNICAL FIELD

The present disclosure relates to a diagnostic and testing module for evaluating high-voltage buses in an electrically powered machine. More specifically, the present disclosure relates to integrating multiple high-voltage buses within an electrically powered vehicle into a diagnostic and testing module for assessment while protecting personnel from accessing equipment energized at high voltages.

### BACKGROUND

Heavy work machines, such as earth moving vehicles or hauling trucks, require significant power to carry out their functions. The machines themselves can be of substantial weight, and their loads require large amounts of power to move. Diesel engines traditionally provide that power, but they can have disadvantages. For instance, supplies of diesel fuel may be far away from a haul route or work location, and diesel machines can generate significant pollution.

Electrically powered machines can provide many advantages over diesel machines, but also pose some challenges. The electric engine and various electrical components in the work machine require significant electrical power at different voltage levels. Whether supplied directly from onboard batteries or from an external source, electrical power within the work machine can exceed several megawatts, and high-voltage buses in the machine can carry several thousand volts. These values lead to a hazardous environment for personnel and for equipment that are not properly protected.

Diagnosing and testing the electric engine and the high-voltage buses can also be a challenge. Personnel need to ensure that the high-voltage buses are safely de-energized before servicing the machine, but the high-voltage buses may be spread throughout the work machine, making it cumbersome to de-energize and possibly dangerous to service the machine safely. Additionally, components that sense and convert the high voltages for use by control systems in the machine and circuitry to evaluate the health of the buses may be distributed with the buses, leading to wasteful redundancy in the system.

One approach for testing for the presence of high voltage in an electric vehicle is described in International Patent App. Pub. No. WO2022/106245A1 (“the '245 application”). The '245 application describes a monitoring device for an electric vehicle having a housing that accepts at least one high voltage input, an access door to provide access to a user interface, at least one electric circuit for monitoring the presence of high voltage, at least one high voltage interlock protection circuit, and a microcontroller. According to the '245 application, the microcontroller and the electric circuit monitor the presence of high voltage, and the high voltage interlock protection circuit and the microcontroller indicate through the user interface when high voltage is present using indicator lights. The monitoring device of the '245 application does not address integrating multiple high-voltage buses into the device, monitoring the health of the buses, or providing power levels of each bus to a machine controller. As a result, the monitoring device of the '245 application is not desirable for diagnosing and testing multiple high-voltage buses in a heavy work machine.

Examples of the present disclosure are directed to overcoming deficiencies of such systems.

### SUMMARY

In an aspect of the present disclosure, a diagnostic and testing module for a high-voltage machine includes a front side, a rear side longitudinally opposite the front side, first busbars configured to receive first voltages from a first electrical bus closer to the rear side than to the front side, and second busbars configured to receive second voltages from a second electrical bus closer to the rear side than to the front side. The module includes first test points extending from the first busbars, second test points extending from the second busbars, and a probing block of electrically insulative material positioned proximate the front side. The probing block includes first slots arranged laterally across the front side and extending longitudinally from the front side to the first test points, and second slots arranged laterally across the front side and extending longitudinally from the front side to the second test points. The first slots and the second slots are configured to receive test probes and to electrically isolate individual ones of the first test points and the second test points. The first slots and the second slots include a bottom and two walls, and the two walls extend from the bottom to a top of the probing block.

In another aspect of the present disclosure, a probing block for a diagnostic and testing module includes a body of insulative material having a front and a rear longitudinally opposite the front, where the rear is configured to receive first test points for a first high-voltage bus and second test points for a second high-voltage bus. The probing block further includes a base and a top vertically opposite the base. First slots are arranged laterally across the front and extend longitudinally from the front to the first test points. Second slots are arranged laterally across the front and extend longitudinally from the front to the second test points, where the first slots and the second slots are configured to receive test probes and to electrically isolate individual ones of the first test points and the second test points. Further, the first slots and the second slots include a bottom and two walls, where the two walls extend from the bottom to a top of the probing block.

In yet another aspect of the present disclosure, a method for accessing high-voltage equipment within an electrically powered machine includes visually inspecting high-voltage indicators within a protective wall of a diagnostic and testing module, verifying a lack of illumination by the high-voltage indicators, and inserting one or more probes into first slots of a probing block at a front side of the diagnostic and testing module. The first slots are arranged laterally across the front side and extend longitudinally from the front side to first test points, where the first slots include a bottom and two walls, and the two walls extend from the bottom to a top of the probing block. The method further includes contacting the one or more probes with one or more of the first test points, verifying the absence of hazardous voltage at the first test points with the one or more probes, and attaching the first test points to ground.

### BRIEF DESCRIPTION OF DRAWINGS

The detailed description references the accompanying figures. In the figures, the left-most digit of a reference number identifies the figure in which the reference number first appears. The same reference numbers indicate similar or identical items.

FIG. 1 is a schematic illustration of an electrically powered work machine coupled to a roadside power source in accordance with an example of the present disclosure.

FIG. 2 is a functional block diagram of a diagnostic and testing module for the work machine of FIG. 1 in accordance with an example of the present disclosure.

FIG. 3 is an isometric front corner view of a schematic illustration of a first diagnostic and testing module in an energized state in accordance with an example of the present disclosure.

FIG. 4 is an isometric rear corner view of a schematic illustration of the first diagnostic and testing module of FIG. 3 in accordance with an example of the present disclosure.

FIG. 5 is a front view of a schematic illustration of the first diagnostic and testing module of FIG. 3 in accordance with an example of the present disclosure.

FIG. 6 is an isometric front corner view of a schematic illustration of the first diagnostic and testing module in a grounded state in accordance with an example of the present disclosure.

FIG. 7 is an isometric front corner view of a schematic illustration of a second diagnostic and testing module in an energized state in accordance with an example of the present disclosure.

FIG. 8 is a flow chart depicting a method for verifying de-energization of an electrically powered machine in accordance with an example of the present disclosure.

### DETAILED DESCRIPTION

Consistent with the principles of the present disclosure, a diagnostic and testing module for an electrically powered vehicle integrates multiple high-voltage buses for assessment while protecting personnel from accessing equipment energized at hazardous voltages. Within the scope of the present disclosure, “high voltage” and “hazardous” voltages are intended to refer to voltage levels that pose a significant threat of human harm in a short-circuit condition, which in most contexts may be above about 50 VDC. The consolidated module contains circuitry for assessing each high-voltage bus. The assessments may include checking for ground faults, generating and distributing a priming voltage before energization of the buses, and identifying a bus voltage exceeding a predetermined hazardous level. Additionally, voltage transducers may sense and convert the high voltages to lower levels and communicate information about the voltages to a controller for use in operating the vehicle. A protective wall separates the high-voltage buses and circuitry at a rear of the module from a probing block at a front of the module. Lamps within the protective wall warn of energized bus voltages above the hazardous level. If the lamps are not illuminated, personnel can verify de-energized bus voltages using test points within the probing block and then install a grounding bar across all test points to ensure de-energization while also preventing re-energization during servicing by the personnel. The following describes several examples for carrying out the principles of this disclosure.

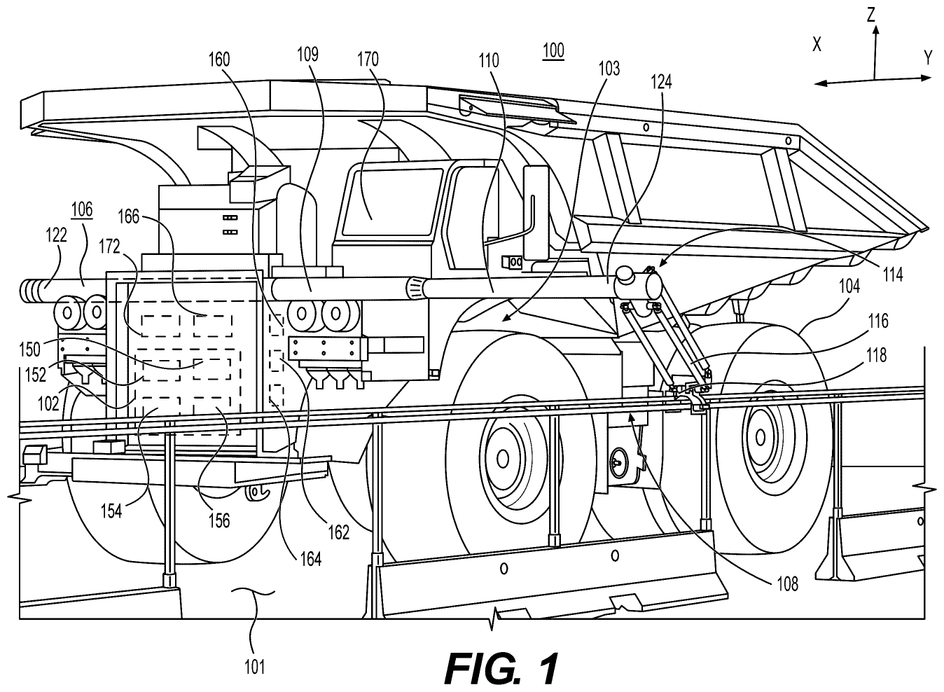

FIG. 1 illustrates an isometric view of a work machine 100 within an XYZ coordinate system as one example suitable for containing the diagnostic and testing module of this disclosure. Exemplary work machine 100 travels parallel to the X axis along a roadway, also termed a haul route 101, typically from a source to a destination within a worksite. In one implementation as illustrated, work machine 100 is a hauling machine that hauls a load within or from a worksite within a mining operation. For instance, work machine 100 may haul excavated ore or other earthen materials from an excavation area along haul route 101 to dump sites and then return to the excavation area. In this arrangement, work machine 100 may be one of many similar machines configured to ferry earthen material in a trolley arrangement. While a large mining truck in this instance, work machine 100 may be any machine that carries a load between different locations within a worksite, examples of which include an articulated truck, an off-highway truck, an on-highway dump truck, a wheel tractor scraper, or any other similar machine. Alternatively, work machine 100 may be an off-highway truck, on-highway truck, a dump truck, an articulated truck, a loader, an excavator, a pipe layer, or a motor grader. In other implementations, work machine 100 need not haul a load and may be any machine associated with various industrial applications including, but not limited to, mining, agriculture, forestry, construction, and other industrial applications.

Referring to FIG. 1, and relevant to the present disclosure, an example work machine 100 includes a frame 103 powered by electric engine 102 to cause rotation of traction devices 104. Traction devices 104 are typically four or more wheels with tires, although tracks or other mechanisms for engagement with the ground along haul route 101 are possible. Electric engine 102 functions to provide mechanical energy to work machine 100 based on electrical power sources, such as described in further detail below. An example of mechanical energy provided by electric engine 102 includes propelling traction devices 104 to cause movement of work machine 100 along haul route 101, but electric engine 102 also includes components sufficient to power other affiliated operations within work machine 100. For instance, in some implementations, electric engine 102 includes equipment for converting electrical energy to provide pneumatic or hydraulic actions within work machine 100. While electric engine 102 is configured to operate from an external electrical power source, electric engine 102 typically includes one or more batteries for storing electrical energy for auxiliary or backup operations, as discussed in more detail below.

With continued reference to FIG. 1, work machine 100 includes an operator station 170. The operator station 170 is configured to seat an operator (not shown). The operator seated in operator station 170 interacts with various control interfaces and/or actuators within operator station 170 to control movement of various components of work machine 100 and/or the overall movement of work machine 100 itself. Thus, control interfaces and/or actuators within operator station 170 allow control of the propulsion of the work machine 100 as well as feedback to the operator on the performance and operation of work machine 100.

Electric engine 102 includes one or more motors 150 responsible for generating torque to propel work machine 100. Motors 150 may be of any suitable type, such as induction motors, permanent magnet motors, switched reluctance (SR) motors, combinations thereof, or the like. Motors 150 are of any suitable voltage, current, and/or power rating. Motors 150 when operating together are configured to propel the work machine 100 as needed for tasks that are to be performed by the work machine 100. For example, the motors 150 may be rated for a range of about 500 volts to about 3000 volts. A motor controller 152 includes control electronics configured to control the operation of motors 150. In some cases, each motor 150 may be controlled by its own motor controller 152. In other cases, all the motors of work machine 100 may be controlled by a single motor controller 152. The motor controller 152 may further include one or more inverters or other circuitry to control the energizing of magnetic flux generating elements (e.g., coils) of motors 150. Motors 150 are mechanically coupled to a variety of drive train components, such as a drive shaft and/or axles or directly to traction devices 104 to propel work machine 100. Although not shown here, there may be one or more motors that are not used for propulsion of the work machine 100, but rather to operate pumps and/or other auxiliary components, such as to operate hydraulic systems.

According to examples of the disclosure, power to energize motors 150 is received from a battery module 154. Battery module 154 may provide power for operating motors 150 and/or other power consuming components (e.g., controllers, cooling systems, displays, actuators, sensors, etc.) of work machine 100. The presently disclosed subject matter is not limited solely to the use of battery power, as other forms of energy may be used in conjunction with the power provided by the battery module 154, including, but not limited to, internal combustion engines or fuel cells, and external electrical sources discussed further below.

Battery module 154 may be of any suitable type and capacity. Battery module 154 includes one or more cells, that when electrically connected, operate as a battery to provide the voltage, current, and/or power requirements of the motors 150. For example, the battery module may include cells forming a lithium ion battery, a lead-acid battery, an aluminum ion battery, a flow battery, a magnesium ion battery, a potassium ion battery, a sodium ion battery, a metal hydride battery, a nickel metal hydride battery, a cobalt metal hydride battery, a nickel-cadmium battery, a wet cell of any type, a dry cell of any type, a gel battery, combinations thereof, or the like. A battery controller 156 monitors and controls various aspects of the battery module 154, such as controlling a temperature of the battery or the prevention of an over discharge condition.

In addition to, or alternative to, obtaining electrical energy from battery module 154, work machine 100 may obtain electrical energy from an external source. For example, work machine 100 further includes a conductor rod 106 configured to receive electrical power from a power rail 108. In some examples, power rail 108 is one or more beams of metal arranged substantially parallel to and a distance above the ground. In FIG. 1, power rail 108 is positioned to be substantially parallel to the X axis and the direction of travel of work machine 100. Support mechanisms hold power rail 108 in place along a distance at the side of haul route 101 for work machine 100 to traverse. While shown in FIG. 1 to the left of work machine 100 as work machine 100 travels in the direction of the X axis, power rail 108 may be installed to the right of work machine 100 or in other locations suitable to the particular implementation.

Power rail 108 provides a source of electrical power for work machine 100 as either AC or DC. In some examples, power rail 108 has two or more conductors, each providing voltage and current at a different electrical pole. In one implementation (e.g., an implementation in which the power rail 108 includes three conductors), one conductor provides positive DC voltage, a second conductor provides negative DC voltage, and a third conductor provides 0 volts relative to the other two conductors. The two powered conductors within power rail 108 can provide a variety of voltage levels, such as a voltage difference greater than 2500 volts, which may be delivered as +1500 VDC and −1500 VDC in one example. These values are exemplary, and other physical and electrical configurations for power rail 108 are available and within the knowledge of those of ordinary skill in the art.

Conductor rod 106 enables electrical connection between work machine 100 and power rail 108, including during movement of work machine 100 along haul route 101. In the example shown in FIG. 1, conductor rod 106 is an elongated arm resembling a pole. FIG. 1 shows conductor rod 106 positioned along a front side of work machine 100, with respect to the direction of travel of work machine 100 in the direction of the X axis. In this arrangement, conductor rod 106 is located in FIG. 1 in the Y-Z plane essentially along the Y axis with a first end near a right side of work machine 100 and a second end at a left side of work machine 100. Conductor rod 106 may be attached to any convenient location within work machine 100, such as to frame 103, in a manner to couple conductor rod 106 to power rail 108. Shown in FIG. 1 as extending to a left side of work machine 100 toward power rail 108, conductor rod 106 may alternatively be arranged to extend to a right side and at any desired angle from work machine 100 such that conductor rod 106 may be coupled to power rail 108 for obtaining electrical power.

As embodied in FIG. 1, conductor rod 106 includes a barrel 109 mounted to frame 103 of work machine 100. Barrel 109 has a hollow interior and may be a conductive metal having suitable mechanical strength and resiliency, such as aluminum. Within, and possibly including barrel 109, conductor rod 106 includes a series of electrical conductors passing longitudinally, at least from a head 122 at a proximal end to a tip 124 at a distal end. Tubular conductors within arm 110 slidably engage with corresponding tubular conductors within barrel 109 to maintain electrical continuity as arm 110 is extended or retracted.

At a position away from work machine 100 at tip 124, a connector assembly 114 provides an interface to power rail 108 via trailing arms 116 and contactor 118. Power rail 108 is typically arranged along a side of haul route 101, and work machine 100 is steered so that it traverses haul route 101 substantially in parallel with power rail 108. In operation, electrical power is accessed from power rail 108 via contactor 118, which remain in contact during movement of work machine 100, and the electrical power is conducted through trailing arms 116 into connector assembly 114 and to work machine 100 for powering electric engine 102 and otherwise enabling operations within work machine 100.

The different voltages provided by battery module 154 and power rail 108, along with other voltages used within work machine 100, may be distributed within the work machine on two or more voltage buses. In one example, work machine 100 has two voltage buses, a battery bus 160 and an accessory bus 162. In this situation, a traction system (not shown) within work machine 100 for propelling traction devices 104 may be configured to operate from a voltage level V1 provided by battery module 154. This battery voltage V1 may be greater than 700 volts, such as 750 VDC-1500 VDC, which would be provided on battery bus 160 from battery module 154 at least to the traction system within work machine 100. Electrical accessories within work machine 100, such as a water pump, an electric fan, a heating, ventilation, and air conditioning (HVAC) system, or a battery thermal management system (BTMS), typically require a lower voltage, so the battery voltage V1 is converted within work machine 100 to a lower DC voltage V2, such as 550 VDC-700 VDC, for distribution on accessory bus 164. In this two-bus example, a higher voltage V3 received from an external source, namely, power rail 108 providing a voltage difference greater than 2500 VDC, such as 2700 VDC-2800 VDC, would be stepped down to match the battery voltage V1 and then joined into battery bus 160.

In another example, work machine 100 has three voltage buses-battery bus 160, accessory bus 162, and a traction bus 164. In this situation, the traction system may be configured to operate from voltage level V3 provided by power rail 108, i.e., at about 2700 VDC-2800 VDC. As a result, battery voltage V1 on battery bus 160 is stepped up to match voltage level V3, i.e., a traction voltage V3 on traction bus 264. Thus, in this example, traction bus 164 carries about 2700 VDC-2800 VDC, while battery bus 160 carries battery voltage V1 of about 750 VDC-1500 VDC, and accessory bus 162 carries a lesser voltage V2 of about 550 VDC-700 VDC. The voltages for each of these buses is exemplary only and other voltage values and ranges may be adopted without departing from the principles of this disclosure.

One or more electronic control modules or units 172 (ECM or ECU) provide centralized processing and control for work machine 100 in coordination with operator station 170. The ECM is a controller as meant to be used in its broadest sense to include one or more controllers and/or microprocessors that may be associated with the work machine 100 and that may cooperate in controlling various functions and operations of the machine. The functionality of ECM 172 may be implemented in hardware and/or software without regard to the functionality. ECM 172 may include or be coupled to a memory (not shown), which may store instructions or algorithms in the form of data, and a processing unit, which may be configured to perform operations based upon the instructions. The memory may be any suitable computer-accessible or non-transitory storage medium for storing computer program instructions, such as RAM, SDRAM, DDR SDRAM, RDRAM, SRAM, ROM, magnetic media, optical media and the like. ECM 172 may be a single controller or multiple controllers working together to perform a variety of tasks.

ECM 172 may embody a single or multiple microprocessors, field programmable gate arrays (FPGAs), digital signal processors (DSPs), and/or other components configured to generate information useful to an operator of work machine 100. Numerous commercially available microprocessors can be configured to perform the functions of ECM 172. Various known circuits may be associated with ECM 172, including power supply circuitry, signal conditioning circuitry, actuator driver circuitry (i.e., circuitry powering solenoids, motors, or piezo actuators), and communication circuitry.

In the context of work machine 100, ECM 172 is configured to receive battery status (e.g., state-of-charge (SOC) or other charge related metrics) from the battery controller 156, operator signal(s), such as an accelerator signal, based at least in part on the operator's interactions with one or more control interfaces and/or actuators of the work machine 100, and other signals and data pertinent to functioning of work machine 100. For example, ECM 172 may receive signals relating to the values of V1 on battery bus 160, V2 on accessory bus 162, and V3 on traction bus 164 and may control behavior of motors 150 via motor controller 152. In some situations, ECM 172 is configured to control the use of energy from battery module 154 in a manner that enhances the range of work machine 100. It should be understood that ECM 172 may control any variety of other subsystems of the work machine 100 to provide work machine 100 with desired operational capability.

In some examples, work machine 100 includes a power electronics cabinet 166 configured to house various high-voltage electrical and magnetic components for operating electric engine 102. These components may generate several megawatts of power, and power electronics cabinet 166 can help isolate dangerous electrical equipment from personnel and from other components of work machine 100. For instance, power electronics cabinet 166 may store one or more inverters used to convert DC voltage to AC voltage to be supplied within the traction system for driving traction devices 104, as well as components for converting or transforming the high DC voltages associated with operating electric engine 102. As a result, at least battery bus 160, accessory bus 162, and traction bus 164 are routed within work machine 100 through power electronics cabinet 166.

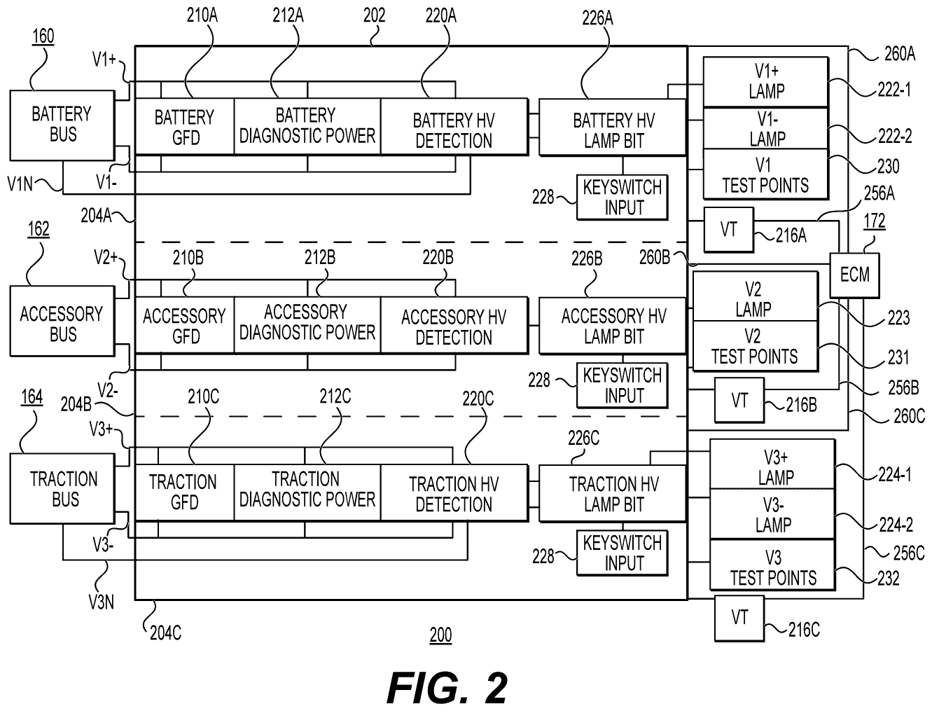

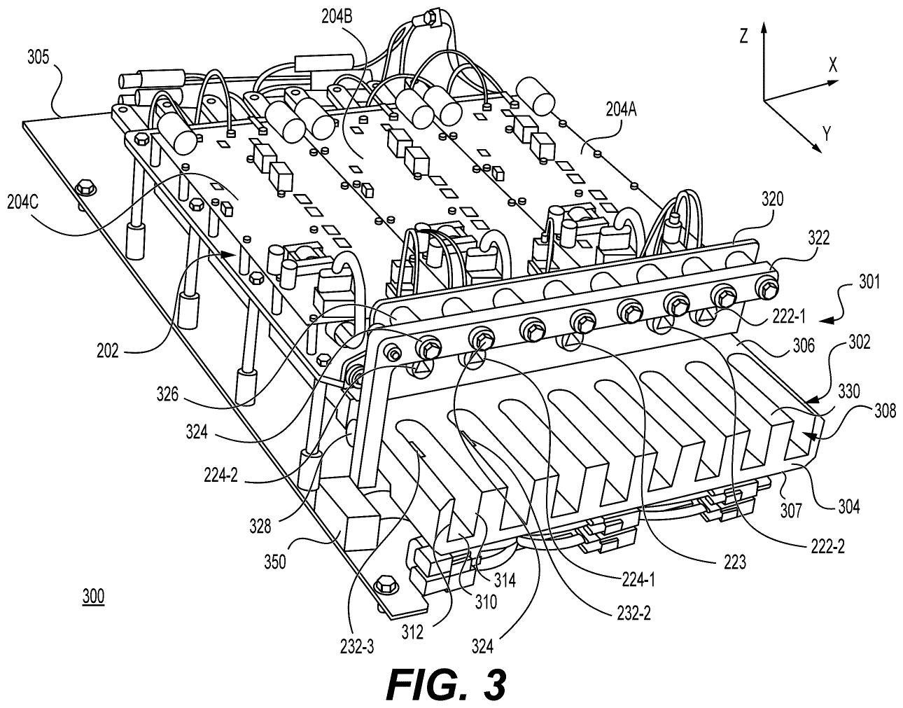

While FIG. 1 provides an overview of work machine 100, FIG. 2 depicts a functional block diagram 200 of a diagnostic and testing module for evaluating health and performance of two or more of the high-voltage buses in work machine 100. As discussed in more detail below with respect to FIGS. 3-7, the diagnostic and testing module may be implemented as a compact and self-contained electronic device that is housed at the entrance to power electronics cabinet 166. This device, referenced as diagnostic and testing module 300 in FIGS. 3-7, acts as a physical and electrical gateway into power electronics cabinet 166 to protect service personnel from hazardous voltages while integrating diagnostic, sensing, and testing functions for two or more of battery bus 160, accessory bus 162, and traction bus 164.

Referring to FIG. 2, the left side of the figure indicates the input of battery bus 160, accessory bus 162, and traction bus 164 for the diagnostic and testing module. The input from battery bus 160, accessory bus 162, and traction bus 164 are provided for purposes of illustration. As discussed above, in some examples work machine 100 may include only two high-voltage buses, such as battery bus 160 and accessory bus 162. For the illustrated example, of FIG. 2, each of the three high-voltage buses is fed into an analysis section 202, which provides diagnostic and analytical functions for the three buses in a single location. To integrate the analytical functions for the three buses, analysis section 202 includes separate subsections for each bus, deemed bus board 204A, bus board 204B, and bus board 204C, separated by dashed lines in FIG. 2. As explained further for FIGS. 3-7, bus board 204A, bus board 204B, and bus board 204C in some examples are implemented as separate printed circuit boards, each containing circuitry required to perform the diagnostic and testing functions for a respective bus. Thus, as illustrated in FIG. 2, battery bus 160 feeds its three conductors containing positive, negative, and neutral polarity of V1+, V1−, and V1N into bus board 204A. For some work machines, V1+ and V1− may carry a nominal voltage difference of 750 VDC to 1500 VDC. Similarly, accessory bus 162 is connected to bus board 204B to provide V2+ and V2−, which for some work machines may provide a nominal voltage difference of 550 VDC to 700 VDC. As well, traction bus 164 is connected to bus board 204C to feed the bus voltages of V3+ and V3−, which for some work machines may provide a nominal voltage difference of 2700 VDC to 2800 VDC.

At the right side of FIG. 2, a series of voltage transducers 216A, 216B, and 216B and affiliated electronics (not shown) are included within the diagnostic and testing module. The voltage transducers, which may be implemented in various types and quantities, are respectively associated with each high-voltage bus. The voltage transducers convert or transform the voltage present on the buses and, along with associated electronics, generate signals representative of sensed values and behavior of the voltage. Thus, voltage transducers 216A convert and sense one or more of V1+, V1−, and V1N and provide related values or measurements to ECM 172 via V1 sensing output 256A. Likewise, voltage transducers 216B and voltage transducers 216C perform the same functions on the voltages received from accessory bus 162 and traction bus 164, respectively, and pass related values or measurements to ECM 172 via V2 sensing output 256B and V3 sensing output 256C. In some examples, ECM 172 processes the information received from voltage transducers 216A, 216B, and 216B to perform a variety of control functions in operating work machine 100, such as monitoring or diagnosing the status or health of the high-voltage buses, overseeing or controlling the operation of electric engine 102 and motors 150, and executing different functions in carrying out the activities by and within work machine 100.

Returning to the left side of FIG. 2, one or more of bus board 204A, bus board 204B, and bus board 204C includes ground-fault detection circuitry (GFD) configured to test for and diagnose any ground faults arising in the cables of an associated high-voltage bus. Thus, for bus board 204A, a battery GFD 210A receives V1+ and V1− and analyzes the bus for ground faults during an energized state of the bus. In some examples, in conjunction with ECM 172, high-frequency pulses are provided on battery bus 160 to test the insulation of the cables on battery bus 160 and to measure for any potential leakage currents to ground. Battery bus test signals 260A, relating to operation of battery GFD 210A and the GFD measurements, are exchanged with ECM 172. Similarly, accessory GFD 210B and traction GFD 210C exchange accessory bus test signals 260B and traction bus test signals 260C, respectively, with ECM 172 and check for ground faults in accessory bus 162 and traction bus 164 during an energized state.

In some examples, the diagnostic and testing module consistent with the present disclosure includes electrical components within one or more of the bus boards to provide diagnostic power on the buses at a lower and safer voltage than the fully energized levels of V1, V2, or V3. For instance, when conducting diagnostics, each of the buses is de-energized from its hazardous level (e.g., hundreds or thousands of volts), and then one or more of battery bus 160, accessory bus 162, and traction bus 164 is energized from the diagnostics and testing module with a lower voltage (e.g., tens of volts).

Referring to functional block diagram 200 of FIG. 2, in one example, battery diagnostic power 212A within bus board 204A contains components configured to receive V1+, V1−, and V1N from battery bus 160 and to generate under control of ECM 172 a voltage of about +20 VDC for V1+ and −20 VDC for V1−. Battery diagnostic power 212A could include circuitry to convert or boost a low voltage source of about 24 VDC to a higher diagnostic or priming level of about 40 VDC. With these lower values energizing battery bus 160 as a test voltage, an operator can perform diagnostics and testing on battery bus 160 with less risk of harm. In some situations, battery diagnostic power 212A can be activated to help prepare work machine 100 prior to full energization, i.e., pre-energization, such as safely verifying the lack of a short circuit within battery bus 160, checking health of the bus, and calibrating the measurements of voltage transducers 216A at a lower voltage. Likewise, accessory diagnostic power 212B and traction diagnostic power 212C can be activated together or separately in coordination with ECM 172 to generate a priming level of voltage on accessory bus 162 and traction bus 164, respectively.

In accordance with the principles of this disclosure, a diagnostic and testing module as conceptually represented by functional block diagram 200 in FIG. 2 also, or alternatively, includes access protection to ensure the safety of personnel attempting to work on one or more of the high-voltage buses or their associated components. Access protection may include several safeguards for personnel to check and verify that the buses are de-energized before working around the buses, such as within power electronics cabinet 166, or on the diagnostics and testing module itself. Access protection can include at least visual safeguards and physical or electrical safeguards, as explained below.

FIG. 2 illustrates that each bus board of analysis section 202 includes circuitry configured to evaluate voltage levels on a respective bus, to determine whether those voltages exceed predetermined values, and to provide visual notification of the presence of high voltage. These circuits in functional block diagram 200 are denominated battery HV detection 220A, accessory HV detection 220B, and traction HV detection 220C. The HV detection circuitry can vary based on the implementation and will be known to those of ordinary skill in the field.

In some examples, the HV detection circuitry will be configured to provide at least a visual indication of high voltage to personnel when the voltage across a full bus (e.g., the voltage between V1+ and V1−) exceeds 50 VDC or across half a bus (e.g., the voltage between V1+ and V1N or between V1− and V1N) exceeds 25 VDC. When the predetermined high-voltage level is exceeded, the HV detection circuits cause illumination of one or more associated warning indicators or lamps. Thus, battery HV detection 220A may illuminate V1+ lamp 222-1 and/or V1− lamp 222-2 if a full-bus voltage exceeding 50 VDC or a half-bus voltage exceeding 25 VDC is detected for battery bus 160. Similarly, accessory HV detection 220B may cause V2 lamp 223 to illuminate if the voltage between V2+ and V2− exceeds 50 VDC for accessory bus 162, and traction HV detection 220C may cause V3+ lamp 224-1 and V3− lamp 224-2 to illuminate if a full-bus voltage exceeding 50 VDC or a half-bus voltage exceeding 25 VDC is detected for traction bus 164. In some examples, each of the high-voltage lamps is powered by its affiliated bus, i.e., V1+ lamp 222-1 and V1− lamp 222-2 are powered by voltage on battery bus 160. While lamps or lights are preferred to provide visual indication of danger, other forms of communication such as audible warnings may also or alternatively be used.

Additionally, analysis section 202 may include various built-in-test circuits (BIT) to assist in identify system errors. In one example, V1 BIT 226A is associated with battery HV detection 220A and configured to identify an open-circuit or a short-circuit condition on battery bus 160. In particular, V1 BIT 226A monitors the current passing through V1+ lamp 222-1 and V1− lamp 222-2 and, if the current level rises or falls outside a predetermined nominal range when hazardous voltage is present on the bus (e.g., a full-bus voltage exceeding 50 VDC or a half-bus voltage exceeding 25 VDC) for battery bus 160, a fault condition is registered and communicated to ECM 172. Whether the conclusion is that an open circuit or a short circuit has arisen, ECM 172 may cause an alarm to be activated to warn the operator or other personnel. In some examples, the alarm will continue to annunciate until a key switch input 228, typically present in operator station 170, is cycled and the fault is no longer present. The fault would no longer be present if the current flowing to the relevant HV lamp returns to its predetermined nominal range or the voltage identified by battery HV detection 220A is no longer a hazardous voltage for battery bus 160 (e.g., a full-bus voltage equal to or below 50 VDC or a half-bus voltage equal to or below 25 VDC). Similar functionality would exist for V2 BIT 226B and key switch input 228 for accessory bus 162 and for V3 BIT 226C and key switch input 228 for traction bus 164.

The diagnostic and testing module depicted in functional block diagram 200 includes a physical or electrical safeguard in the form of external test points, such as V1 test points 230, V2 test points 231, and V3 test points 232. The test points may include contacts accessible by personnel to check the voltage on one or more of battery bus 160, accessory bus 162, and traction bus 164 using test equipment. Therefore, following indication from the HV lamps of a safe condition for accessing the module and the buses, service personnel may manually verify the de-energization of one or more of the buses using probes on V1 test points 230, V2 test points 231, and V3 test points 232.

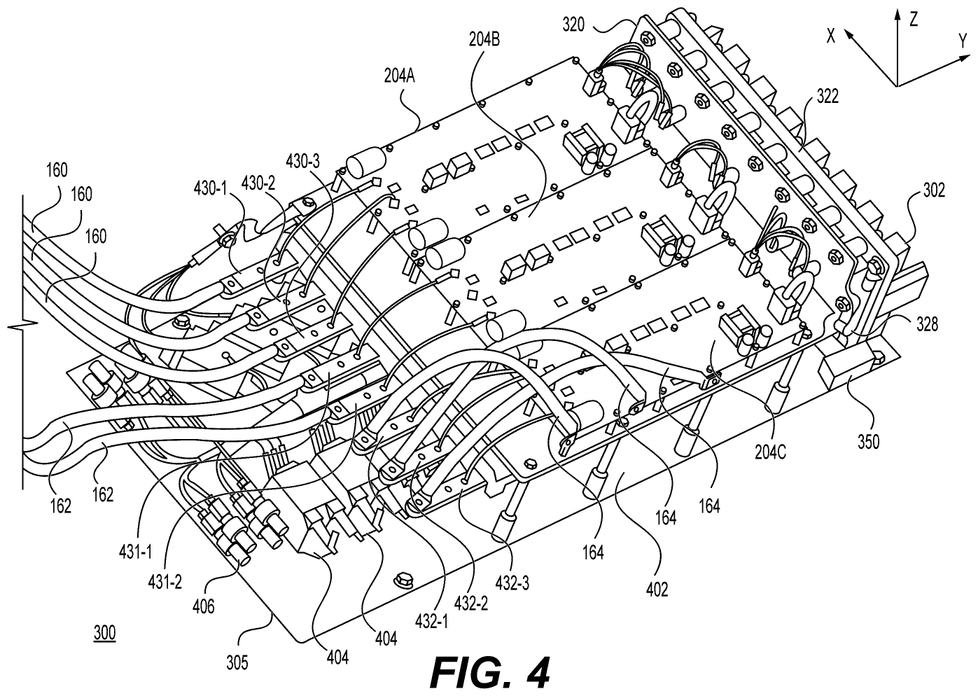

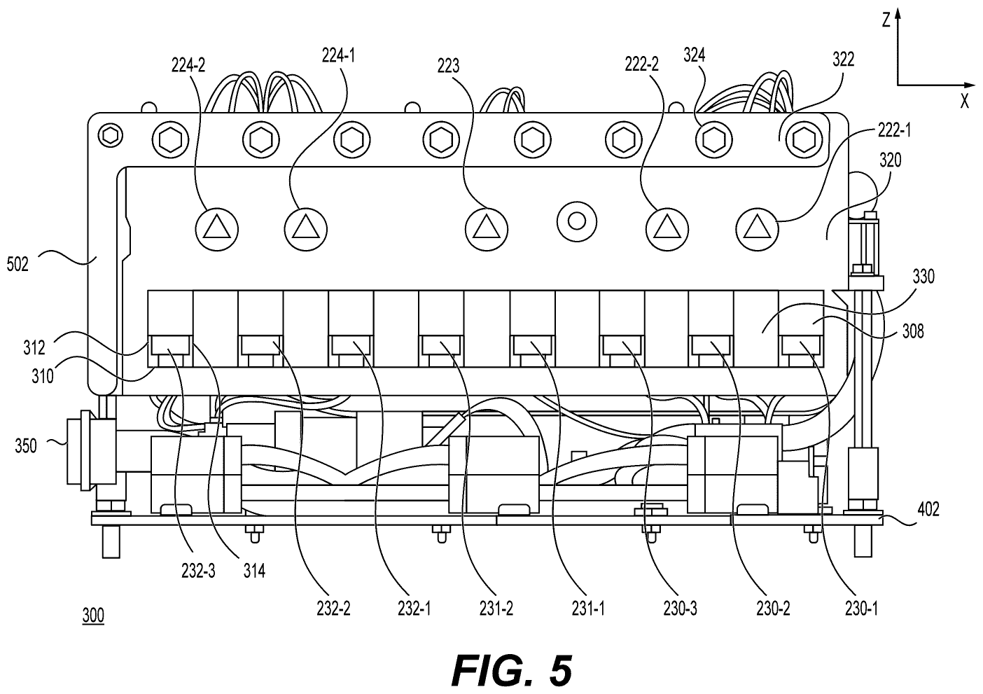

While functional block diagram 200 in FIG. 2 illustrates general features of a diagnostic and testing module that integrates multiple high-voltage buses in a work machine 100, FIGS. 3 and 4 depict one physical implementation of a diagnostic and testing module 300 consistent with those features and with the principles of the present disclosure. FIG. 3 is a front corner isometric view of diagnostic and testing module 300, while FIG. 4 provides a rear corner isometric view of the module. For ease of discussion, FIGS. 3 and 4 as well as FIGS. 5-7 depict diagnostic and testing module 300 within an XYZ coordinate system, which does not necessarily correspond with the XYZ coordinate system for work machine 100 in FIG. 1.

Referring to FIGS. 3 and 4 together, diagnostic and testing module 300 is embodied as a compact device for consolidating or integrating the diagnostic and testing functions for two or more high-voltage buses, along with access protection to ensure personnel safety. In some examples, diagnostic and testing module 300 is mounted within power electronics cabinet 166, possibly with a front 304 being adjacent to and parallel with an opening into the cabinet. For instance, front 304 may generally abut closed doors (not shown) of power electronics cabinet 166 in a manner discussed in more detail below. In the implementation illustrated, diagnostic and testing module 300 is organized to have voltage sensing functions for each of the buses mounted on a baseboard 402 as part of a lower or base section of diagnostic and testing module 300, analysis section 202 with bus board 204A, bus board 204B, and bus board 204C for each of the respective buses positioned on an upper or elevated section above baseboard 402, and access protection section 301 located within front 304 of diagnostic and testing module 300, such as adjacent the closed doors of power electronics cabinet 166.

Cables for each of battery bus 160, accessory bus 162, and traction bus 164 are connected to busbars 430, busbars 431, and busbars 432, respectively, toward rear 305 of the module. Specifically, the respective voltages on battery bus 160 pass through busbars 430-1, busbars 430-2, and busbars 430-3, which then are fed to baseboard 402 as well as to bus board 204A. Similar input occurs through busbars 431-1 and busbars 431-2 into baseboard 402 and bus board 204B for accessory bus 162 and through busbars 432-1, busbars 432-2, and busbars 432-3 into baseboard 402 and bus board 204C for traction bus 164. Positioning of these high-voltage inputs close to rear 305 helps isolate high voltages from any access by personnel though an opening of power electronics cabinet 166 near front 304.

Within baseboard 402, voltage transducers 216 include transformers 404 to transform voltage levels on the buses received on busbars 430, busbars 431, and busbars 432 as part of operation of energized work machine 100 and in support of battery HV detection 220A, accessory HV detection 220B, and traction HV detection 220C. Other circuits may be included with transformers 404 to provide voltage sensing functionality, such as resistors 406 to convert currents to voltages. Diagnostic and testing module 300 receives instructions from ECM 172 for the sensing operations and responds to ECM 172 with detected data through signal port 350. In some examples, signal port 350 is a multi-pin connector for attaching to a communications cable to exchange signals with ECM 172.

Through the connection between busbars 430 and bus board 204, analysis section 202 can evaluate voltages received from energized buses to determine whether they exceed a predetermined high-voltage level or, when controlled by ECM 172, can generate diagnostic power for assessing the bus health or for performing other functions on de-energized buses. Specifically, as discussed above for FIG. 2, bus board 204A in FIGS. 3 and 4 can include circuitry for executing the functions of battery diagnostic power 212A and battery HV detection 220A, bus board 204B can include circuitry for executing the functions of accessory diagnostic power 212B and accessory HV detection 220B, and bus board 204C can include circuitry for executing the functions of traction diagnostic power 212C and traction HV detection 220C.

In some examples, protective wall 320 extends along the X-Z plane and serves as a barrier generally separating at least analysis section 202 from access protection section 301. With access protection section 301 being positioned near to an opening in power electronics cabinet 166 where personnel may work, protective wall 320 helps prevent inadvertent contact with electronics within analysis section 202 or with the high voltages on busbars 430, 431, or 432. Within a surface of protective wall 320 in the X-Z plane, one or more of V1+ lamp 222-1, V1− lamp 222-2, V2 lamp 223, V3+ lamp 224-1, and V3− lamp 224-2 are visible. As discussed above for FIG. 2, these lamps are hazardous voltage indicators that illuminate if the full-bus voltage or the half-bus voltage on any of battery bus 160, accessory bus 162, or traction bus 164 exceeds a predetermined value, such as 50 VDC or 25 VDC at any time. It is expected that personnel would not enter power electronics cabinet 166 when any of the lamps are illuminated. In some examples, doors on power electronics cabinet 166 may include a translucent portion to enable viewing of the hazardous voltage indicators without opening the doors. Other provisions for enhancing the viewability of the hazardous voltage indicators or otherwise being informed of the high-voltage detection are also within the scope of the present disclosure.

As generally embodied in FIG. 3, access protection section 301 in diagnostic and testing module 300 further includes a probing block 302 across its front side farthest along the Y axis. The front corner view of diagnostic and testing module 300 in FIG. 5 shows that V1 test points 230, V2 test points 231, and V3 test points 232 may be exposed for access by personnel. These test points are electrically connected to, and may be extensions of, busbars 430, 431, and 432 shown in FIG. 4. Accordingly, test points 230, 231, and 232 provide physical contacts for personnel to attach a meter or other electrical device to directly measure the electrical activity on any one of battery bus 160, accessory bus 162, and traction bus 164. Probing block 302 is an insulative material, such as a glass-reinforced thermoset polyester (GPO-3), formed to protect against inadvertent contact with test points 230, 231, or 232, such as V3− test point 232-2 or V3n test point 232-3 shown in FIG. 3.

In some examples, probing block 302 generally forms a cuboid having cavities or slots 308 corresponding to each of busbars 430, 431, and 432. With this configuration, probing block 302 helps protect against inadvertent contact with test points longitudinally along the Y axis in FIG. 3, laterally along the X axis, and vertically along the Z axis, while also enabling visibility of the test points by personnel. Longitudinally, probing block 302 provides insulative material along a distance separating front 304 from test points 230, 231, and 232. This distance helps block personnel, or probes handled by personnel, from unintentionally reaching the test points. Laterally, probing block 302 includes separators 330 between each of slots 308 at a sufficient height and width to help guard against inadvertent movement of probes or other equipment along the X axis between test points. Vertically, the height of separators 330 from slot bottom 310 to top 306 additionally blocks probes or other equipment from being moved downwardly along the Z axis unintentionally to reach the test points. At the same time, in some examples, slots 308 within probing block 302 are open vertically. Thus, while slot bottom 310, slot first wall 312, and slot second wall 314 may define a squared U-shape for slots 308 to confine a probe entering the module to contact a test point, such as V3n test point 232-3 in FIG. 3, top 306 does not extend over slots 308. Consequently, personnel facing the front 304 can look downward to see the test points at the end of each of the slots 308, which can assist with accurate placement of a probe in contact with one of the test probes.

While probing block 302 in FIG. 3 depicts probing block 302 as having a comb-shaped configuration, with probing block 302 being a cuboid and slots 308 being longitudinal cavities with substantially rectangular cross-sections, other geometric configurations for probing block 302 are possible and within the scope of the present disclosure. For instance, each of probing block 302 and slots 308 could be curved or rounded depending on the implementation. In some examples, top 306 may extend over all of slots 308, blocking vertical access to slots 308. Additional features to guard against inadvertent access to or between test points 230, 231, and 232 are within the knowledge and experimentation of those of ordinary skill in the field.

FIG. 5 illustrates a front view of diagnostic and testing module 300 in one implementation, showing the accessibility along the Y axis of test points 230, 231, and 232 through slots 308. The lamps indicating a high voltage on the buses are positioned within protective wall 320 near the test points for those buses and within the likely line of sight for personnel looking toward front 304. Specifically, V1+ lamp 222-1 and V1− lamp 222-2 are located above and between V1 test points 230-1, V1 test points 230-2, and V1 test points 230-3; V2 lamp 223 is located above and between V2+ test point 231-1 and V2− test point 231-2; and V3+ lamp 224-1 and V3− lamp 224-2 are located above and between V3+ test point 232-1, V3− test point 232-2, and V3n test point 232-3. Accordingly, in attempting to service work machine 100, personnel can first view the status of the high-voltage lamps and, upon not seeing a high-voltage indication for a particular bus, the personnel can verify that indication using probes on the corresponding test points in a process discussed further below.

Referring to FIGS. 3 and 5, diagnostic and testing module 300 in some examples includes a grounding bar 322 shown mounted in a stowed position. In this stowed position, bolts 324 attach and hold grounding bar 322 through spacers 326 to protective wall 320. Grounding bar 322 may be a conductive material having at least a first portion with a generally rectangular shape, such as that portion extending along the X axis in FIGS. 3 and 5. In some examples, grounding bar 322 has at least a second portion as arm 502 extending along the Z axis to give grounding bar 322 an overall L-shape. Ground strap 328, which is a flexible and conductive material, connects grounding bar 322 to electrical ground within diagnostic and testing module 300. Grounding bar 322 may remain in the stowed position as shown in FIGS. 3 and 5 except during servicing of diagnostic and testing module 300 or other high-voltage equipment within work machine 100.

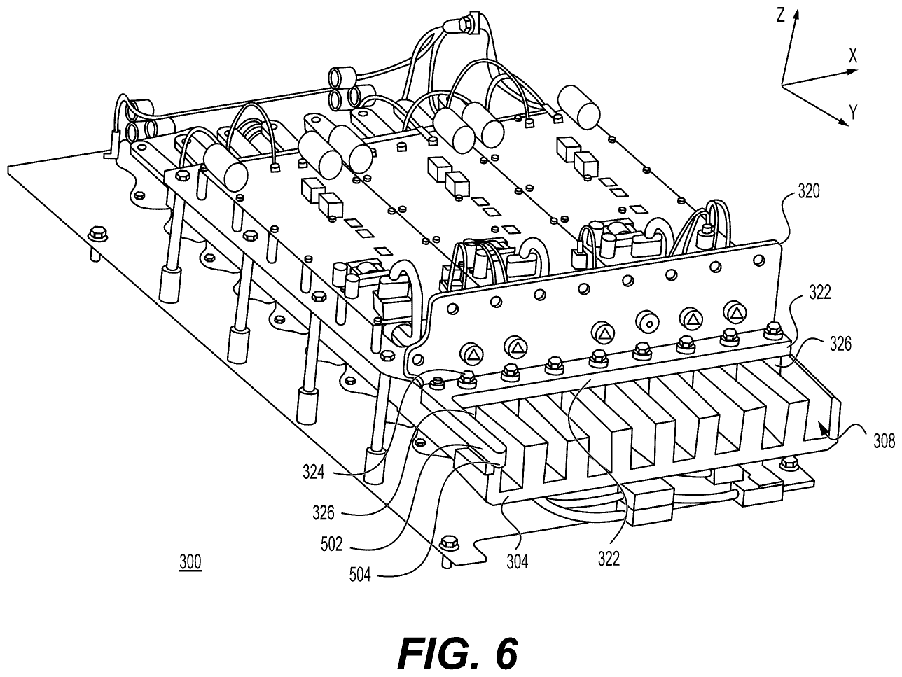

When servicing of diagnostic and testing module 300 or high-voltage equipment within work machine 100 takes place, grounding bar 322 may be moved from its stowed position to a grounding position. In particular, after personnel have verified that the high-voltage buses are de-energized through checking visually that the high-voltage lamps are not illuminated and through applying probes to the test points, bolts 324 can be removed from protective wall 320 to release grounding bar 322 from its stowed position where arm 502 extends downwardly along the Z axis, as shown in FIGS. 3 and 5. Grounding bar 322 may then be rotated to an orientation as shown in FIG. 6, where arm 502 extends forwardly along the Y axis and spacers 326 are inserted into each of the corresponding slots 308. As illustrated, spacers 326 are substantially cylindrical in shape and are made of conductive material, such as copper. Spacers 326 extend from grounding bar 322 for a distance sufficient to provide a secure electrical connection between grounding bar 322 and each of the test points within slots 308, i.e., between top 306 of probing block 302 and V1 test points 230, V2 test points 231, and V3 test points 232 within slots 308. Bolts 324 passing through spacers 326 then secure grounding bar 322 in the grounding position, as shown in FIG. 6. In this grounding position, grounding bar 322, spacers 326, and ground strap 328 provide a path to ground for each of battery bus 160, accessory bus 162, and traction bus 164, ensuring de-energization of the high-voltage buses. This grounding and de-energization provides a safe condition for personnel to operate on high-voltage equipment within work machine 100, or specifically on diagnostic and testing module 300, while also preventing re-energization of the high-voltage buses.

In some examples, the structure of grounding bar 322 can help warn personnel from re-energizing work machine 100 when in the grounding position. Beyond the visual indication of grounding bar 322 being installed over probing block 302 and within slots 308, arm 502 facing forward indicates that that all high-voltage buses are currently grounded. Additionally, arm 502 may be dimensioned so that tip 504 extends beyond front 304 along the Y axis on probing block 302. This extension can make visual detection easier and can provide an abutment to the closing of doors within power electronics cabinet 166. Thus, when diagnostic and testing module 300 is mounted in power electronics cabinet 166 such that closed doors of the cabinet are adjacent to front 304, the extension of tip 504 on arm 502 can block the complete closure of at least one door of the cabinet. If servicing of work machine 100 is complete, personnel may recognize that the buses remain grounded by one or more doors of power electronics cabinet 166 not being able to close fully.

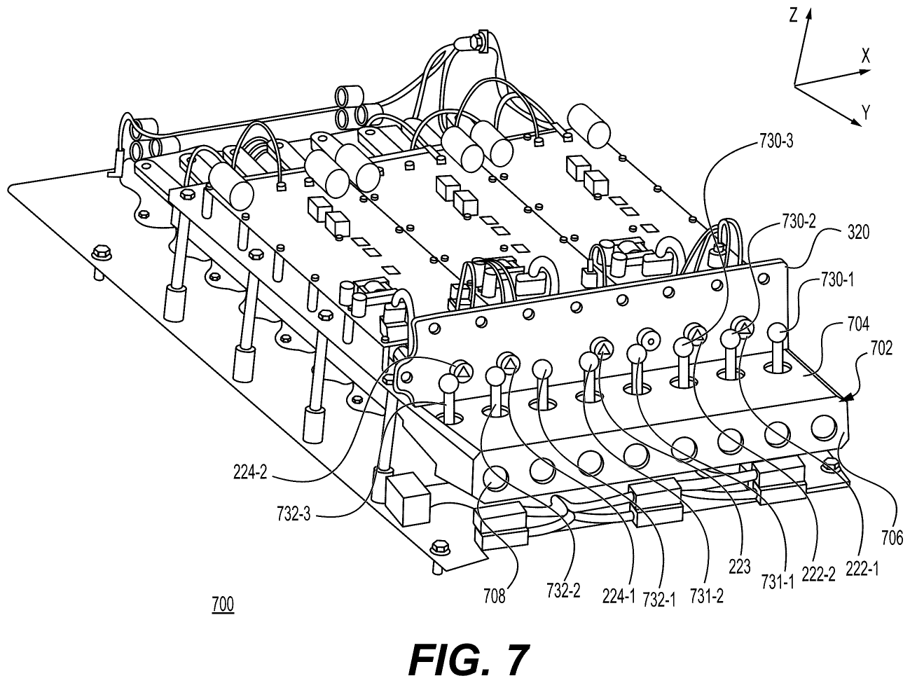

FIG. 7 depicts a diagnostic and testing module 700 having an alternative version of access protection. In diagnostic and testing module 700, probing block 702 may also have a substantially cuboid shape but with openings 708 rather than slots 308 across a front 706. Each of openings 708 correspond to one of test points 230, 231, and 232, and provide a longitudinal passageway along the Y axis for a probe to reach a respective test point, as with probing block 302. Although not shown, vertical protections or walls, such as separators 330 for diagnostic and testing module 300, can provide isolation between openings 708 to help prevent inadvertent movement of a probe to other test points.

In accordance with the principles of this disclosure, diagnostic and testing module 700 includes V1 ball studs 730, V2 ball studs 731, and V3 ball studs 732 in place of grounding bar 322 of diagnostic and testing module 300. Each of the ball studs is an electrically conductive material and is connected to a corresponding one of busbars 430, 431, and 432. Specifically, V1+ ball stud 730-1, V1− ball stud 730-2, and Vin ball stud 730-3 are connected to busbars 430-1, busbars 430-2, and busbars 430-3, respectively, as are V2 ball studs 731 with busbars 431 and V3 ball studs 732 with busbars 432. After verifying the absence of illumination on any of the high-voltage lamps and the absence of hazardous voltage on any of the buses by inserting probes into openings 708 to reach test points 230, 231, and 232, personnel can attach grounding cables between each of V1 ball studs 730, 731, and 732 and ground. As with grounding bar 322 for diagnostic and testing module 300, grounding cables for diagnostic and testing module 700 will force battery bus 160, accessory bus 162, and traction bus 164 to ground and prevent those buses from being energized.

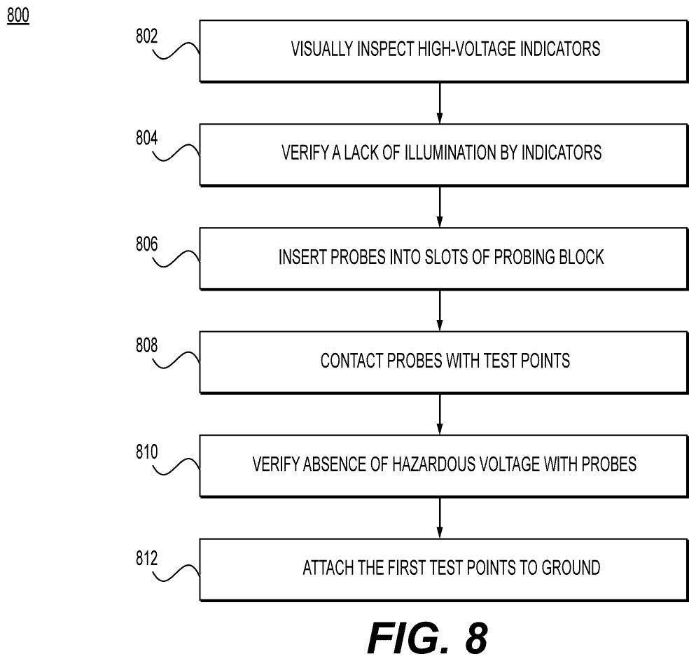

Turning from the structure and operation of diagnostic and testing module 300 and diagnostic and testing module 700 as illustrated in FIG. 2-7 to a method involving these modules, FIG. 8 is a flowchart of a representative method for verifying de-energization of a battery-powered machine. Generally embodied as 800 in FIG. 8, the method begins with step 802 of visually inspecting high-voltage indicators within a protective wall of a diagnostic and testing module. As explained above with respect to FIGS. 3 and 5, for example, a work machine 100 may include diagnostic and testing module 300 having warning lamps 222, 223, and 224 installed on protective wall 320. When personnel wish to work on equipment within work machine 100 subject to hazardous voltages, such as equipment within power electronics cabinet 166, personnel can first check the status of warning lamps 222, 223, and 224. These lamps, lights, or other devices provide a visual or other sensory indication and may be driven by battery HV detection 220A, accessory HV detection 220B, and traction HV detection 220C in analysis section 202. When voltage levels exist on a respective one of battery bus 160, accessory bus 162, or traction bus 164 above a predetermined hazardous level, e.g., above 50 VDC, corresponding warning lamps 222, 223, or 224 will illuminate for the personnel to observe.

Method 800 continues with a second step 804 of verifying a lack of illumination by the high-voltage indicators. Because the illumination of warning lamps 222, 223, or 224 indicates that hazardous voltage exists on one of the high-voltage buses, observing the absence of illumination acts as a first check against working around dangerous voltages. In some examples, front 304 of diagnostic and testing module 300 may be installed at the opening of power electronics cabinet 166, and the warning lamps may be observable through closed doors of power electronics cabinet 166, such as through a window of translucent material. In that circumstance, personnel may choose to open the doors of power electronics cabinet 166 only with the absence of illumination by the high-voltage indicators.

In a third step 806, one or more probes are inserted into first slots of a probing block at a front side of the diagnostic and testing module, and, in a fourth step 808, the one or more probes are contacted with the one or more of the first test points. In some examples, the first slots are arranged laterally across the front side and extend longitudinally from the front side to first test points within the probing block. As illustrated in an example of FIG. 3, the first slots may include a slot bottom 310, a slot first wall 312, and a slot second wall 314, where the two walls extend from slot bottom 310 to a top 306 of the probing block 302. The first test points may be tips of busbars 430 that extend through a backside of the first slots in probing block 302, which are reachable by probes with the first slots.

After contacting the first test points, the absence of hazardous voltage at the first test points is verified with the one or more probes in a step 810 of FIG. 8. In some examples, the probes may be attached to electrical test equipment, such as a voltmeter, to determine the electrical activity on the test points and, therefore, the associated high-voltage bus. Other options exist for determining electrical activity at the test points from inputs received from probes.

In a last step 812, the first test points are attached to ground. As discussed above for at least FIGS. 3, 6, and 7, grounding of the test points could be accomplished in different options. In a first option using grounding bar 322, bolts 324 are removed from grounding bar 322 to release the bar from protective wall 320. The spacers 326 with grounding bar 322 are then inserted into slots 308 of probing block 302, and bolts 324 are inserted into threaded holes within the test points, such as V1 test points 230. In this option, ground strap 328 may remain attached to grounding bar 322 to complete a path from the test points to electrical ground. In a second option for diagnostic and testing module 700 shown in FIG. 7, grounding cables may be attached to ball studs, or similar terminals connected with the busbars, and to electrical ground. With either option, the high-voltage buses are securely tied to ground to avoid inadvertent energization of the buses during maintenance or other activity by personnel within power electronics cabinet 166 or otherwise near high-voltage equipment of work machine 100.

Those of ordinary skill in the field will appreciate that the principles of this disclosure are not limited to the specific examples discussed or illustrated in the figures. For example, while the diagnostic and testing module has been discussed in the context of an electrically powered work machine, other uses for them are feasible. The module could be implemented in other electrical equipment containing high-voltage buses. In addition, the principles disclosed are not limited to implementation on work machines. In addition, any electrically powered vehicle could benefit from the examples and techniques disclosed and claimed. Moreover, while the present disclosure addresses a diagnostic and testing module with three high-voltage buses, implementations having more or fewer buses are contemplated.

### INDUSTRIAL APPLICABILITY

The present disclosure provides a diagnostic and testing module for an electrically powered machine and methods for verifying de-energization of the electrically powered machine. The diagnostic and testing module integrates multiple high-voltage buses for assessment in a consolidated device while protecting personnel from accessing equipment energized at hazardous voltages. With similar or redundant circuitry, the consolidated module assesses each high-voltage bus, including checking for ground faults, generating and distributing a priming voltage before energization of the buses, and identifying a bus voltage exceeding a predetermined hazardous level. A protective wall separates the high-voltage buses and circuitry at a rear of the module from a probing block at a front of the module. Lamps within the protective wall warn of energized bus voltages above the hazardous level. If the lamps are not illuminated, personnel can verify de-energized bus voltages using test points within the probing block and then install a grounding bar across all test points to ensure de-energization.

As noted above with respect to FIGS. 1-8, a diagnostic and testing module such as 300 in FIG. 3 may be positioned within the opening of a power electronics cabinet 166 of an electrically powered machine 100. The module includes a front side 304, possibly facing outwardly from the opening, and a rear side 305 longitudinally opposite the front side. First busbars 430 and second busbars 431 are configured to receive first voltages from a first electrical bus 160 and second voltages from a second electrical bus 162. First and second test points 222, 223 extend from the first and second busbars. A probing block 302 of electrically insulative material is positioned proximate the front side and contains first and second slots 308 arranged laterally across the front side and extending longitudinally from the front side to the first test points and the second test points. The first and second slots include a bottom 310 and two walls 312, 314, with the two walls extending from the bottom to a top of the probing block. The slots are configured to receive test probes and to electrically isolate individual ones of the first test points and the second test points.

In the examples of the present disclosure, a diagnostic and testing module for an electrically powered vehicle consolidates assessment and security functions for multiple high-voltage buses at single location, avoiding the need and lowering risks of working among high-voltage buses dispersed within a machine. The consolidated module enables sensing and measuring of high voltages, both for safety and for use by a controller for operating the electrically powered vehicle. Additionally, separate circuits can detect ground faults in each bus and can generate and distribute a low-level priming voltage for verifying the health of de-energized buses. The protective wall 320 with hazardous-voltage indicators 222, 223, 224 and probing block 302 at the front of the module increases safety for personnel, and a grounding bar 322 moveable between a stowed and grounding state guards against accidental bus energizations.

Unless explicitly excluded, the use of the singular to describe a component, structure, or operation does not exclude the use of plural such components, structures, or operations or their equivalents. As used herein, the word “or” refers to any possible permutation of a set of items. For example, the phrase “A, B, or C” refers to at least one of A, B, C, or any combination thereof, such as any of: A; B; C; A and B; A and C; B and C; A, B, and C; or multiple of any item such as A and A; B, B, and C; A, A, B, C, and C; etc.

Terms of approximation are meant to include ranges of values that do not change the function or result of the disclosed structure or process. For instance, the term “about” generally refers to a range of numeric values that one of skill in the art would consider equivalent to the recited numeric value or having the same function or result. Similarly, the antecedent “substantially” means largely, but not wholly, the same form, manner or degree, and the particular element will have a range of configurations as a person of ordinary skill in the art would consider as having the same function or result.

While aspects of the present disclosure have been particularly shown and described with reference to the embodiments above, it will be understood by those skilled in the art that various additional embodiments may be contemplated by the modification of the disclosed systems and methods without departing from the spirit and scope of what is disclosed. Such embodiments should be understood to fall within the scope of the present disclosure as determined based upon the claims and any equivalents thereof.

What is claimed is:

1. A diagnostic and testing module for a high-voltage machine, comprising:
a front side;
a rear side longitudinally opposite the front side;
first busbars configured to receive first voltages from a first electrical bus closer to the rear side than to the front side;
second busbars configured to receive second voltages from a second electrical bus closer to the rear side than to the front side;
first test points extending from the first busbars;
second test points extending from the second busbars; and
a probing block of electrically insulative material positioned proximate the front side, the probing block comprising:
first slots arranged laterally across the front side and extending longitudinally from the front side to the first test points, and
second slots arranged laterally across the front side and extending longitudinally from the front side to the second test points,
wherein the first slots and the second slots are configured to receive test probes and to electrically isolate individual ones of the first test points and the second test points, wherein the first slots and the second slots include a bottom and two walls, the two walls extending from the bottom to a top of the probing block.

2. The diagnostic and testing module of claim 1, further comprising:
first circuitry configured to detect a ground fault within one of the first electrical bus and the second electrical bus; and
second circuitry configured to generate a priming voltage for testing one of the first electrical bus and the second electrical when in a de-energized state.

3. The diagnostic and testing module of claim 2, further comprising third circuitry configured to sense levels of the first voltage and the second voltages.

4. The diagnostic and testing module of claim 1, wherein the first circuitry and the second circuitry are contained within circuit boards elevated above the third circuitry.

5. The diagnostic and testing module of claim 1, wherein the first slots have a width and depth, the width being laterally between the two walls, the depth being longitudinally from the front side to the first test points and being greater than the width.

6. The diagnostic and testing module of claim 1, wherein the first slots and the second slots are open between the two walls at the top of the probing block.

7. The diagnostic and testing module of claim 6, further comprising:
a protective wall positioned longitudinally adjacent the first test points and the second test points, the protective wall extending vertically above the top of the probing block; and
a grounding bar, in a stowed position, attached with bolts into the protective wall.

8. The diagnostic and testing module of claim 1, wherein the top of the probing block extends between the two walls of the first slots and the second slots, the module further comprising:
ball studs rising vertically through the top of the probing block, individual ones of the ball studs being connected to respective ones of the first test points and the second test points.

9. The diagnostic and testing module of claim 1, further comprising third busbars configured to receive third voltages from a third electrical bus, the first voltages being greater than 700 VDC, the second voltages being less than 700 VDC, and the third voltages being greater than 2500 VDC.

10. The diagnostic and testing module of claim 1, further comprising:
a protective wall positioned longitudinally adjacent the first test points and the second test points, the protective wall extending vertically above the top of the probing block;
first bus indicators mounted on the protective wall above the first test points, the first bus indicators being configured to illuminate when the first voltages exceed a predetermined voltage level; and
second bus indicators mounted on the protective wall above the second test points, the second bus indicators being configured to illuminate when the second voltages exceed the predetermined voltage level.

11. A probing block for a diagnostic and testing module, comprising:
a body of insulative material, the body having:
a front,
a rear longitudinally opposite the front, the rear being configured to receive first test points for a first high-voltage bus and second test points for a second high-voltage bus;
a base, and
a top vertically opposite the base;
first slots arranged laterally across the front and extending longitudinally from the front to the first test points; and
second slots arranged laterally across the front and extending longitudinally from the front to the second test points,
wherein the first slots and the second slots are configured to receive test probes and to electrically isolate individual ones of the first test points and the second test points, wherein the first slots and the second slots include a bottom and two walls, the two walls extending from the bottom to a top of the probing block.

12. The probing block of claim 11, wherein the first slots have a width and depth, the width being laterally between the two walls, the depth being longitudinally from the front to the rear and being greater than the width.

13. The probing block of claim 11, wherein the first slots and the second slots are open between the two walls at the top of the probing block.

14. The probing block of claim 13, wherein the top of the probing block extends between the two walls of the first slots and the second slots.

15. The probing block of claim 11, wherein the first high-voltage bus provides first voltages greater than 700 VDC, the second high-voltage bus provides second voltages less than 700 VDC, and the diagnostic and testing module is part of an electrically powered vehicle.

16. The probing block of claim 11, further comprising third slots arranged laterally across the front and extending longitudinally from the front to third test points, wherein the probing block contains at least eight of the first slots, the second slots, and the third slots.

17. A method for accessing high-voltage equipment within an electrically powered machine, comprising:
visually inspecting high-voltage indicators within a protective wall of a diagnostic and testing module;
verifying a lack of illumination by the high-voltage indicators;
inserting one or more probes into first slots of a probing block at a front side of the diagnostic and testing module, the first slots being arranged laterally across the front side and extending longitudinally from the front side to first test points, wherein the first slots include a bottom and two walls, the two walls extending from the bottom to a top of the probing block;
contacting the one or more probes with one or more of the first test points;
verifying the absence of hazardous voltage at the first test points with the one or more probes; and
attaching the first test points to ground.

18. The method of claim 17, further comprising:
inserting the one or more probes into second slots of the probing block at the front side of the diagnostic and testing module, the second slots being arranged laterally across the front side and extending longitudinally from the front side to second test points, wherein the second slots include a bottom and two walls, the two walls of the second slots extending from the bottom to the top of the probing block;
contacting the one or more probes with one or more of the second test points;
verifying the absence of hazardous voltage at the second test points with the one or more probes; and
attaching the second test points to ground.

19. The method of claim 18, wherein attaching the first test points to ground and attaching the second test points to ground comprises:
removing a grounding bar from a stowed position attached to the protective wall, a grounding strap connecting the grounding bar to ground; and
attaching the grounding bar into a ground position over the probing block and in contact with the first test points and the second test points.

20. The method of claim 18, wherein attaching the first test points to ground and attaching the second test points to ground comprises:
attaching grounding cables between ground and ball studs extending through the top of the probing block, the ball studs being connected to the first test points and the second test points.

21. A diagnostic and testing module for a high-voltage machine, comprising:
a front side;
a rear side longitudinally opposite the front side;
first busbars configured to receive first voltages from a first electrical bus closer to the rear side than to the front side;
second busbars configured to receive second voltages from a second electrical bus closer to the rear side than to the front side;
first test points extending from the first busbars along a horizontal plane;
second test points extending from the second busbars along the horizontal plane; and
a protective wall positioned longitudinally adjacent the first test points and the second test points, the protective wall extending along a vertical plane above the first test points and the second test points; and
a grounding bar, extending across a width of the diagnostic and testing module, the grounding bar being attached to the protective wall along the vertical plane in a stowed position and being attached to the first test points and the second test points along the horizontal plane in a grounding position.

22. A diagnostic and testing module for a high-voltage machine, comprising:
a front side;
a rear side longitudinally opposite the front side;
first busbars configured to receive first hazardous voltages from a first electrical bus closer to the rear side than to the front side;
second busbars configured to receive second hazardous voltages from a second electrical bus closer to the rear side than to the front side;
circuit boards attached to the busbars longitudinally between the busbars and the front side, one or more of the circuit boards configured for executing diagnostic and test functions on the first electrical bus and on the second electrical bus;
a protective wall positioned longitudinally between the circuit boards and the front side, the protective wall extending vertically above the circuit boards;
hazardous-voltage indicators, coupled to the one or more of the circuit boards and mounted within the protective wall, the hazardous-voltage indicators being exposed to the front side; and
a probing block of insulative material positioned between the protective wall and the front side, the probing block including slots arranged laterally across the front side extending longitudinally from the front side to respective test points of the first busbars and the second busbars.
